(19) United States
(12) Patent Application Publication
(10) Pub. No.: US 2013/0128432 A1
(43) Pub. Date: May 23, 2013

(54) PORTABLE ELECTRONIC DEVICE

(71) Applicant: ASUSTEK COMPUTER INC., TAIPEI (TW)

(72) Inventors: Chia-Jung LEE, Taipei (TW); Chang-Yi TSENG, Taipei (TW)

(73) Assignee: ASUSTEK COMPUTER INC., TAIPEI (TW)

(21) Appl. No.: 13/658,454

(22) Filed: Oct. 23, 2012

Related U.S. Application Data
(60) Provisional application No. 61/562,226, filed on Nov. 21, 2011.

(51) Int. Cl. H05K 7/00

(52) U.S. Cl. 361/679.01

(57) ABSTRACT

A portable electronic device includes a base, a supporting element and a body. The supporting element is pivotally connected to the base and the supporting element includes a connecting part which rotates relatively to the supporting element. The body includes an attaching surface, one side of the body abuts against the base, and the attaching surface is magnetically connected to the connecting part. The position where the body abuts against the base is taken as a supporting point, and the connecting part is connected to the attaching surface at different positions to form different angles between the body and the base.

### CROSS REFERENCE TO RELATED APPLICATIONS

This application claims the priority benefit of U.S. provisional patent application with Ser. No. 61/562,226, filed on Nov. 21, 2011. The entirety of the above-mentioned patent application is hereby incorporated by reference herein and made a part of specification.

### BACKGROUND OF THE INVENTION

1. Field of Invention

The invention relates to an electronic device and, more particularly, to a portable electronic device.

2. Related Art

As the flourishing development of science and information, requirement of retrieving information instantly and conveniently has significantly increased. Thus, many portable electronic devices with various functions, such as a mobile phone, a notebook and a tablet computer, are emerged.

Conventionally, a portable electronic device includes multiple components, and most of the components cannot be detached from each other after assembly. Recently, a computer of which a tablet computer and a keyboard can be detached is produced, a connecting part of the keyboard and the tablet computer is at a pivot of the tablet computer, and the user should press a release key to detach them. Furthermore, since the conventional tablet computer with the keyboard is supported only via the pivot, when the user touches the screen of the tablet computer via fingers, the tablet computer may sway due to insufficient support.

### SUMMARY OF THE INVENTION

A portable electronic device includes a base, a supporting element and a body. The supporting element is pivotally connected to the base, and the supporting element includes a connecting part which rotates relatively to the supporting element. The body includes an attaching surface, one side of the body abuts against the base, and the attaching surface is magnetically connected to the connecting part. A position where the body abuts against the base is taken as a supporting point, and the connecting part is connected to the attaching surface at different positions to form different angles between the body and the base.

These and other features, aspects and advantages of the present invention will become better understood with regard to the following description, appended claims, and accompanying drawings.

### BRIEF DESCRIPTION OF THE DRAWINGS

FIG. 1A is a schematic diagram showing a portable electronic device in a first embodiment;

FIG. 1B is an exploded diagram showing the portable electronic device in FIG. 1A;

FIG. 2A is a side view of the portable electronic device in FIG. 1A;

FIG. 2B is a schematic diagram showing the portable electronic device in FIG. 2A in another angle;

FIG. 2C is a schematic diagram showing the portable electronic device in FIG. 2A in another angle;

FIG. 2D is a schematic diagram showing the magnetic element in FIG. 2A in another embodiment;

FIG. 3 is a schematic diagram showing the portable electronic device in a closed state in FIG. 1A;

FIG. 4A is a schematic diagram showing a portable electronic device in a second embodiment;

FIG. 4B is a schematic diagram showing a portable electronic device in a third embodiment; and

FIG. 4C is a schematic diagram showing the portable electronic device in a closed state in FIG. 4B.

### DETAILED DESCRIPTION OF THE INVENTION

A portable electronic device is illustrated with relating figures, and the same symbols denote the same components.

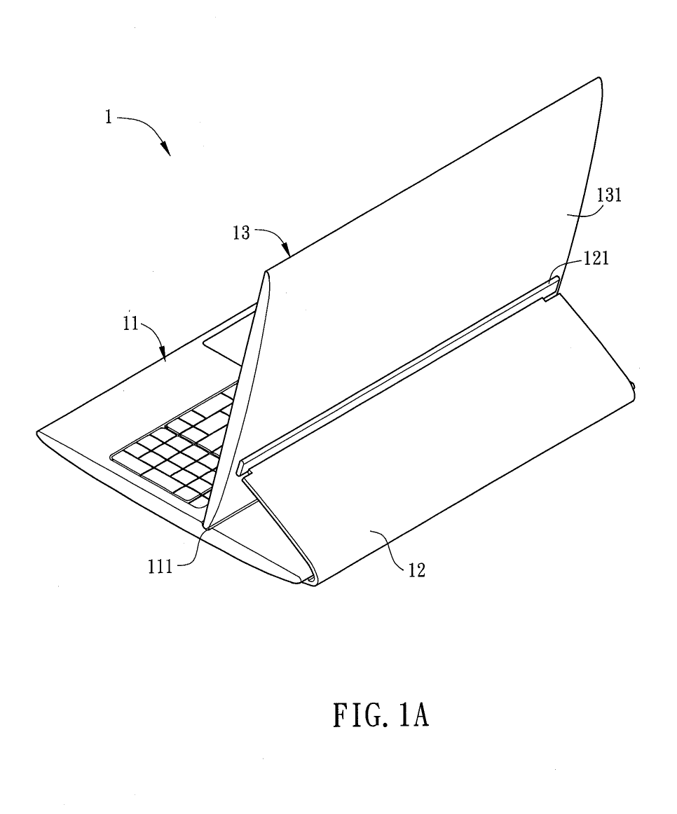

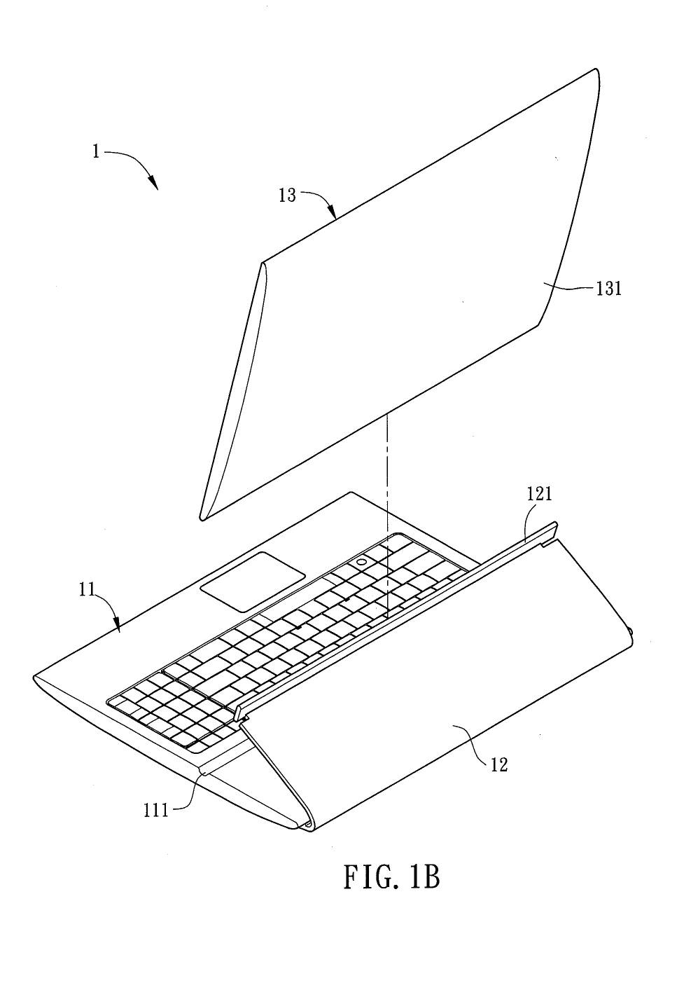

FIG. 1A is a schematic diagram showing a portable electronic device in a first embodiment, and FIG. 1B is an exploded diagram showing the portable electronic device in FIG. 1A. Please refer to FIG. 1A and FIG. 1B, the portable electronic device 1 includes a base 11, a supporting element 12 and a body 13. The supporting element 12 is pivotally connected to the base 11, and the supporting element 12 includes a connecting part 121 which rotates relatively to the supporting element 12.

The body 13 is a tablet computer which includes an attaching surface 131, one side of the body 13 abuts against the base 11, and the attaching surface 131 magnetically connects to the connecting part 121. In an embodiment, the base 11 may include a keyboard or other input modules, and expansion units such as a connecting port, which is not limited herein. The position where the body 13 abuts against the base 11 is taken as a supporting point, and the connecting part 121 is connected to the attaching surface 131 at different positions to form different angles between the body 13 and the base 11. Moreover, the body 13 or the connecting part 121 includes at least one magnetic element.

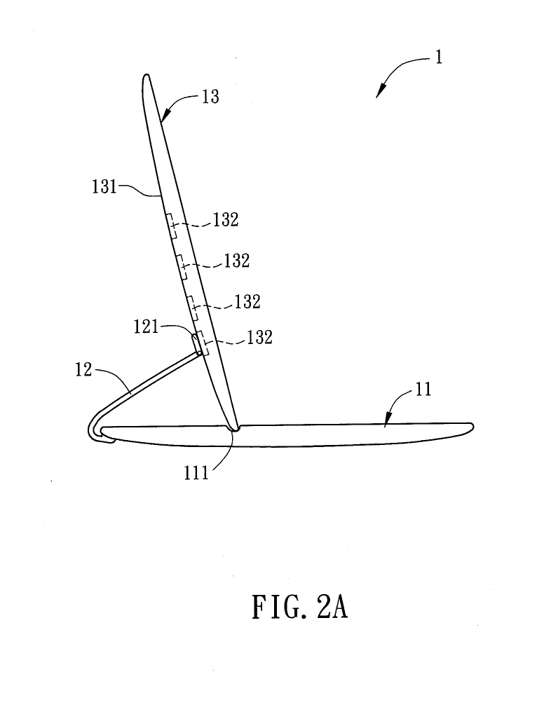

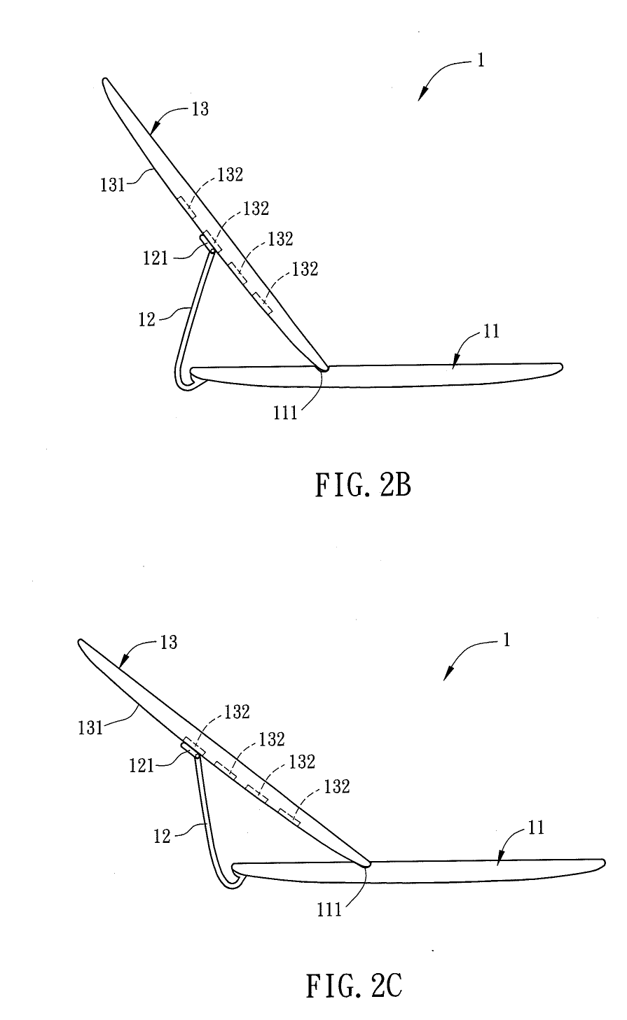

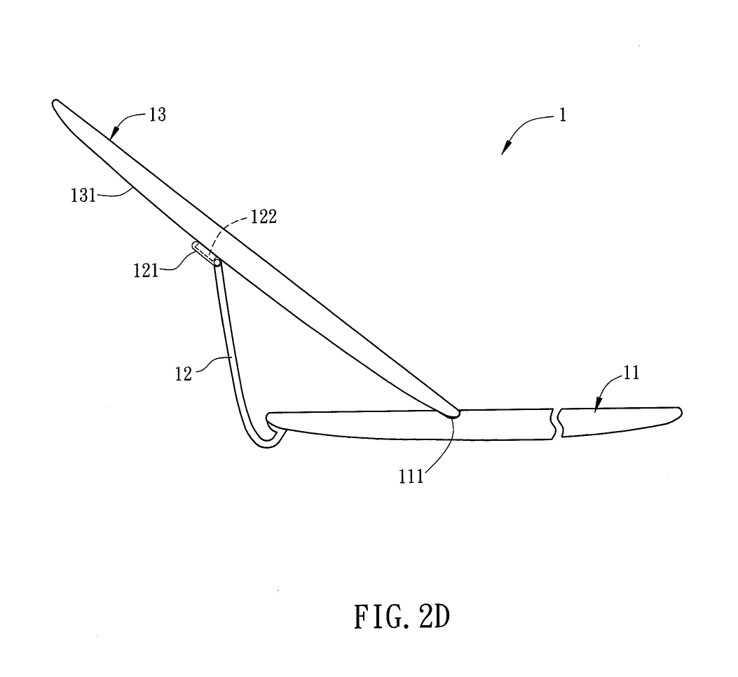

FIG. 2A is a side view of the portable electronic device in FIG. 1A, and FIG. 2B FIG. 2C are schematic diagrams showing the portable electronic device in FIG. 2A in different angles. As shown in FIG. 2A, the body 13 includes a plurality of magnetic elements 132. The magnetic elements 132 may be disposed in the attaching surface 131 of the body 13 at intervals. The connecting part 121 may be made of metal or magnetic material, which is not limited herein, as long as the connecting part 121 can be magnetically connected to the attaching surface 131 of the body 13. FIG. 2D is a schematic diagram showing the magnetic element in FIG. 2A in another embodiment. As shown in FIG. 2D, the magnetic element 122 can also be disposed in the connecting part 121, and the attaching surface 131 of the body 13 is made of metal or magnetic material. The connecting part 121 and the attaching surface 131 can be magnetically connected via the two connecting methods, and the user can detach the body 13 from the base 11 easily, which improves convenience in usage.

Please refer to FIG. 2A to FIG. 2C, since the magnetic elements 132 are disposed in the attaching surface 131 of the body 13 at intervals and the supporting element 12 is rotatably and pivotally connected to the base 11, after the supporting element 12 is magnetically connected to the body 13 via the connecting part 121, the body 13 can be placed at different angles to meet the requirements of the user. In an embodiment, the magnetic element 132 may also be a single element having a large area to achieve the same function, which is not limited herein.

Furthermore, the connecting part 121 is rotatably connected to the supporting element 12, and thus the connecting part 121 can attach to the body 13. If the supporting element 12 does not include the connecting part 121, the body 13 is connected to one side of the supporting element 12, and the area of the side is rather smaller than the contacting area between the connecting part 121 and the body 13. Thus, the body 13 includes insufficient support and is unstable. In other words, the connecting part 121 can reinforce the stableness of the body 13 when it is disposed at the base 11, and further solve the problem of swaying due to insufficient support. The connecting method between the connecting part 121 and the supporting element 12 is not limited, as long as the connecting part 121 can rotate relatively to the supporting element 12. For example, in an embodiment, the connecting part 121 is pivotally connected to the supporting element 12. Besides, the connecting part 121 may also be made of pliable material, the connecting portion between the connecting part 121 and the supporting element 12 is thin, and thus the connecting part 121 can rotate relatively to the supporting element 12.

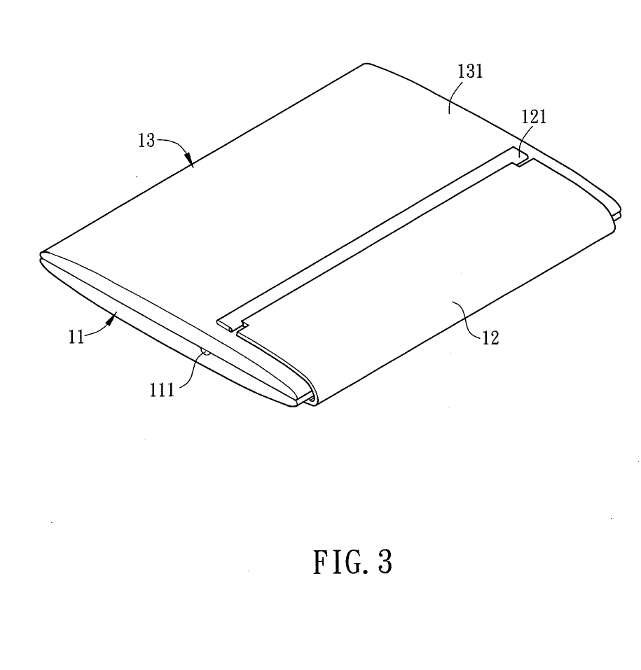

FIG. 3 is a schematic diagram showing the portable electronic device in a closed state in FIG. 1A. Since the base 11 and the supporting element 12 include two pivots, that is, the supporting element 12 is pivotally connected to the base 11, and the connecting part 121 is rotatably connected to the supporting element 12, the portable electronic device 1 is easy to be packed. In other words, when the body 13 is placed flatly on the base 11, the supporting element 12 and the connecting part 121 can also be placed flatly on the body 13 due to the two pivots of the base 11 and the supporting element 12, so as to save space.

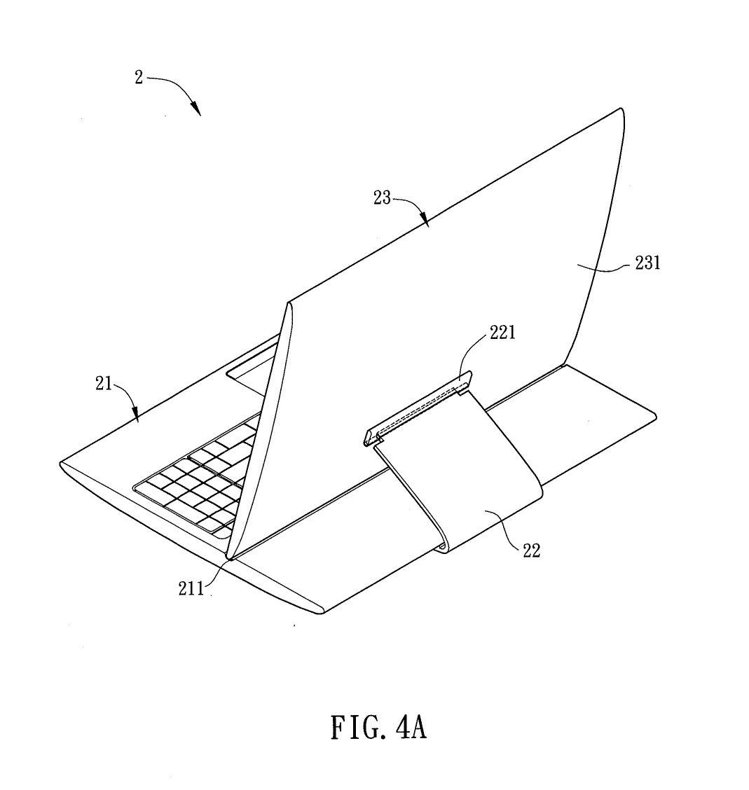

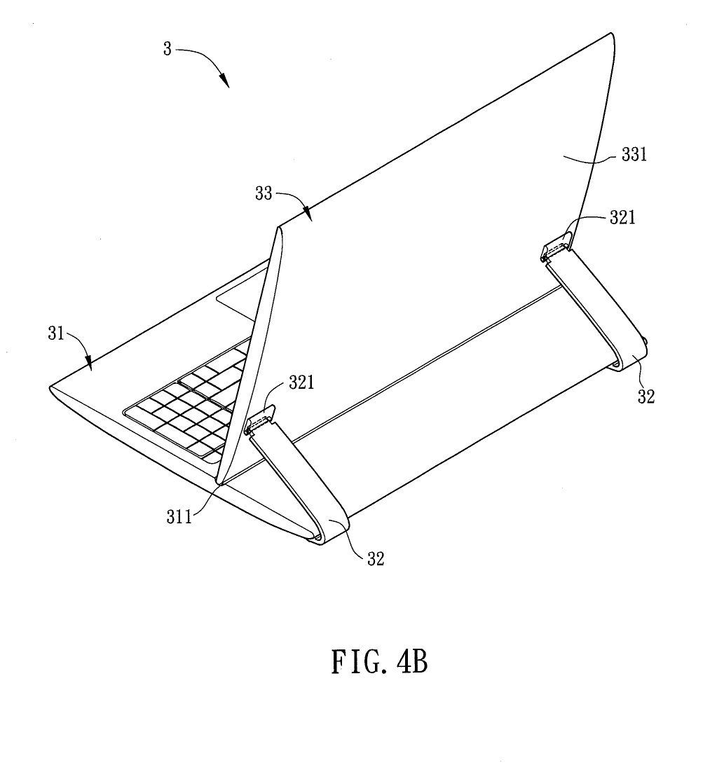

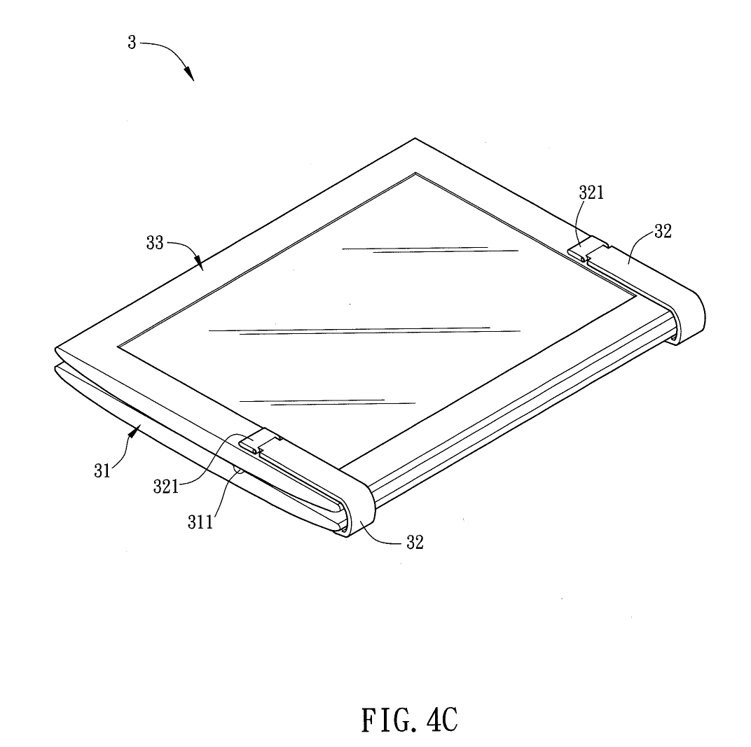

The supporting element of the portable electronic device is not limited, and as long as it can provide an appropriate supporting force for the body. FIG. 4A is a schematic diagram showing a portable electronic device in a second embodiment. The portable electronic device 2 includes a base 21, a supporting element 22 and a body 23. The body 23 is magnetically connected to the supporting element 22, and the size of the supporting element 22 is large enough to support the body 23. FIG. 4B is a schematic diagram showing a portable electronic device in a third embodiment. The portable electronic device 3 includes a base 31, a supporting element 32 and a body 33. The body 33 is magnetically connected to the supporting element 32. The supporting element 32 is disposed at two sides of the base 31, respectively, so that when the portable electronic device 3 is at a closed state, the user still can operate the body 33 (as shown in FIG. 4C).

Moreover, the base 11 further includes a fixing part 111 providing a resisting force to fix the body 13 in the fixing part 111. The fixing part 111 is not limited, and it may be a groove, a protruding part or a magnetic component. In the embodiment, the fixing part 111 is a groove, and the body 13 is stuck in the fixing part 111. Additionally, the fixing part 111 is electronically connected to the body 13, and thus the base 11 can exchange data and power with the body 13.

In sum, in the portable electronic device, the attaching surface of the body is magnetically connected to the connecting part of the supporting element, and thus the body is easy to be detached from the base, which is more convenient comparing to the conventional release key. The supporting element reinforces the supporting force of the base for the body, which solves the problem that the body sways due to insufficient support when the user touches the screen on a conventional body which is only supported by the pivot. Furthermore, since the connecting part of the supporting element is magnetically connected to the attaching surface of the body, the connecting position of the supporting element and the body can be changed to adjust the angle between the body and the base.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A portable electronic device, comprising:
a base;
a supporting element pivotally connected to the base, wherein the supporting element includes a connecting part which rotates relatively to the supporting element; and
a body including an attaching surface, wherein one side of the body abuts against the base, and the attaching surface is magnetically connected to the connecting part;
wherein a position where the body abuts against the base is taken as a supporting point, and the connecting part is connected to the attaching surface at different positions to form different angles between the body and the base.

2. The portable electronic device according to claim 1, wherein the body or the supporting element includes at least a magnetic element.

3. The portable electronic device according to claim 1, wherein the base further includes a fixing part, and the body is placed at the fixing part.

4. The portable electronic device according to claim 3, wherein the fixing part includes a groove, a protruding part or a magnetic component.

5. The portable electronic device according to claim 3, wherein the fixing part is electrically connected to the body.

6. The portable electronic device according to claim 1, wherein the connecting part is made of pliable material.

7. The portable electronic device according to claim 1, wherein the body is a tablet computer.

8. The portable electronic device according to claim 1, wherein the supporting element and the connecting part are integratedly formed.
